(19) United States
(12) Patent Application Publication
(10) Pub. No.: US 2025/0350099 A1
(43) Pub. Date: Nov. 13, 2025

(54) CIRCUIT ASSEMBLY

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Jo SUGIURA, Osaka (JP); Hideyuki KUBOKI, Osaka (JP); Yusuke ISAJI, Osaka (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 18/874,881

(22) PCT Filed: Jun. 19, 2023
(86) PCT No.: PCT/JP2023/022536

§ 371 Date: Jul. 29, 2025

(30) Foreign Application Priority Data
Jun. 27, 2022 (JP) 2022-102932

(51) Int. Cl. H02B 1/56; H02B 1/20; H05K 7/20

(52) U.S. Cl. CPC H02B 1/56; H02B 1/20; H05K 7/20872

(57) ABSTRACT

A circuit assembly includes a heat generating component and a current-carrying bus bar. The current-carrying bus bar includes a hollow duct that extends through the current-carrying bus bar and includes a first opening that is open at one end of the current-carrying bus bar and a second opening that is open at the other end, a first connecting pipe, which is connected in a fluid-tight manner to a first end of the current-carrying bus bar, surrounds the first opening, and communicates with the first opening, and a second connecting pipe, which is connected in a fluid-tight manner to another end of the current-carrying bus bar, surrounds the second opening, and communicates with the second opening. The first connecting pipe includes a first pipe connection port connectable to a refrigerant source, and the second connecting pipe includes a second pipe connection port connectable to the refrigerant source.

### TECHNICAL FIELD

The present disclosure relates to a circuit assembly including a heat-generating component.

### BACKGROUND ART

In the past, vehicles have been equipped with a circuit assembly including a heat-generating component, such as a relay. As one example, Patent Document 1 discloses a circuit assembly in which a first bus bar connected to an output terminal of a battery, a second bus bar connected to an input terminal of a load, and a relay connected between the first and second bus bars are housed in a case. In this circuit assembly, to dissipate the heat generated by the relay, which is a heat-generating component, to the outside, a structure is used where the bus bar connected to the relay is pressed against the case of a battery, which serves as a heat dissipater, via a sheet-like heat conducting member and an electrically insulating member so that heat generated by the relay is transferred to the case.

### CITATION LIST

### Patent Documents

Patent Document 1: JP 2018-93711A

### SUMMARY OF INVENTION

### Technical Problem

However, with the structure disclosed in Patent Document 1, the bus bar needs to be in contact with the heat dissipater via a heat conducting member. The heat conducting member also needs to be interposed between the bus bar and the heat dissipater for the purpose of absorbing tolerances. This results in an unavoidable reduction in heat dissipation efficiency.

For this reason, a circuit assembly is disclosed that can reduce the mounting area occupied by a heat conducting member inside a case and improve the heat dissipation efficiency for the heat generating component through use of a current-carrying bus bar.

### Solution to Problem

A circuit assembly according to an aspect of the present disclosure includes: a heat generating component; and a current-carrying bus bar that is connected to a connector portion of the heat generating component, wherein the current-carrying bus bar includes a bolt fastening portion including a bolt insertion hole and a hollow duct, which extends through an inside of the current-carrying bus bar and includes a first opening that is open at a first end in a length direction of the current-carrying bus bar and a second opening that is open at another end in the length direction of the current-carrying bus bar, the current-carrying bus bar further includes a first connecting pipe, which is connected in a fluid-tight manner to the first end of the current-carrying bus bar, surrounds the first opening, and communicates with the first opening, and a second connecting pipe, which is connected in a fluid-tight manner to the second end of the current-carrying bus bar, surrounds the second opening, and communicates with the second opening, the first connecting pipe includes a first pipe connection port that is connectable to an external refrigerant source, and the second connecting pipe includes a second pipe connection port that is connectable to the refrigerant source.

### Advantageous Effects of Invention

According to an aspect of the present disclosure, it is possible to provide a circuit assembly that can reduce the mounting area occupied by a heat conducting member inside a case and improve the heat dissipation efficiency for the heat generating component through use of a current-carrying bus bar.

### BRIEF DESCRIPTION OF DRAWINGS

FIG. 1 is a perspective view of a circuit assembly according to a first embodiment.

FIG. 2 is a diagram illustrating a specific example of the electrical configuration of the circuit assembly depicted in FIG. 1.

FIG. 3 is an exploded perspective view of the circuit assembly depicted in FIG. 1.

FIG. 4 is a perspective view of a lower assembly that is included in the circuit assembly depicted in FIG. 1.

FIG. 5 is a plan view of the lower assembly depicted in FIG. 4.

FIG. 6 is a cross-sectional view along a line VI-VI in FIG. 5.

FIG. 7 is a cross-sectional view along a line VII-VII in FIG. 5.

FIG. 8 is a perspective view depicting a circuit assembly according to a second embodiment in a state where an upper case has been removed.

### DESCRIPTION OF EMBODIMENTS

Several embodiments of the present disclosure will first be listed and described in outline.

A circuit assembly according to an aspect of the present disclosure includes: a heat generating component; and a current-carrying bus bar that is connected to a connector portion of the heat generating component, wherein the current-carrying bus bar includes a bolt fastening portion including a bolt insertion hole and a hollow duct, which extends through an inside of the current-carrying bus bar and includes a first opening that is open at a first end in a length direction of the current-carrying bus bar and a second opening that is open at another end in the length direction of the current-carrying bus bar, the current-carrying bus bar further includes a first connecting pipe, which is connected in a fluid-tight manner to the first end of the current-carrying bus bar, surrounds the first opening, and communicates with the first opening, and a second connecting pipe, which is connected in a fluid-tight manner to the second end of the current- carrying bus bar, surrounds the second opening, and communicates with the second opening, the first connecting pipe includes a first pipe connection port that is connectable to an external refrigerant source, and the second connecting pipe includes a second pipe connection port that is connectable to the refrigerant source.

With the circuit assembly according to the present disclosure, the current-carrying bus bar connected to the connector portion of the heat-generating component includes a bolt fastening portion and a hollow duct. A first connecting pipe and a second connecting pipe, which are connected in a fluid-tight manner to the first opening and a second opening at both ends of the current carrying bus bar and are provided with a first pipe connection port and a second pipe connection port which are connectable to an external refrigerant source, are provided. By doing so, the current-carrying bus bar connected to the connector portion of the heat-generating component can be maintained in a state where the component is cooled by the refrigerant from a refrigerant source that is circulated through the hollow duct inside the current-carrying bus bar. As a result, the heat generated by the heat-generating component can be quickly and directly dissipated by the current-carrying bus bar connected to the connector portion of the heat-generating component. This means that the mounting area occupied by a heat conducting member inside the case can be made smaller than in a conventional structure, and the heat dissipation efficiency of the heat-generating component can be advantageously improved through use of the current-carrying bus bar.

Additionally, since the inside of the current carrying bus bar is used to provide a hollow duct through which the refrigerant flows, it is possible to promote the cooling of the heat-generating component while satisfying the need to save space. The current-carrying bus bar is also provided with a bolt fastening portion with a bolt insertion hole, which makes it easy to fasten the bus bar to the connector portion of a heat-generating component and/or any interposed bus bars, thereby achieving the same ease of handling as a typical current-carrying bus bar.

Note that the refrigerant can be supplied from a refrigerant source installed in the vehicle, and although it is possible to use any available refrigerant, it is preferable to use a refrigerant which is an electrical insulator, such as Fluorinert.

It is preferable for the first pipe connection port of the first connecting pipe to protrude to and be open at a side of the current-carrying bus bar and be connected to a refrigerant supply pipe for supplying the refrigerant from the refrigerant source, and for the second pipe connection port of the second connecting pipe to protrude to and be open at the side of the current-carrying bus bar and be connected to a refrigerant return pipe for returning the refrigerant to the refrigerant source.

The first pipe connection port of the first connecting pipe and the second pipe connection port of the second connecting pipe each protrude and are open to the side of the current-carrying bus bar. By doing so it is easy to connect the refrigerant supply pipe and the refrigerant return pipe to the first and second openings of the hollow duct of the current-carrying bus bar, which improves ease of assembly. As a result, the refrigerant from the refrigerant source is supplied from the refrigerant supply pipe through the first opening of the hollow duct of the current-carrying bus bar, and refrigerant that has circulated inside the hollow duct is discharged from the second opening of the hollow duct pipe and returns to the refrigerant source via the refrigerant return pipe. In addition, since the first and second pipe connection ports are both provided to protrude from the side of the current-carrying bus bar, it is possible to provide space for the refrigerant supply pipe and the refrigerant return pipe at a location outside the routing region of the current-carrying bus bar, thereby further improving the ease of assembly. Since the first and second pipe connection ports are each provided so as to protrude to the side of the current-carrying bus bar, the height of the circuit assembly can be reduced even when the refrigerant supply pipe and the refrigerant return pipe have been assembled, which advantageously satisfies demands to save space.

It is preferable for the current-carrying bus bar to include a central region where a central part in a width direction extends with a predetermined width and a pair of side regions that extend with a predetermined width on both sides in the width direction of the central region, for the central region to be formed so that parts aside from the bolt insertion holes are solid along an entire length in the length direction, and for the hollow duct, which passes through in the length direction, to be provided in at least one of the side regions. Since the bolt insertion hole is provided in the central region provided in the central part in the width direction, the bolt fastening portion can be provided in a central part in the width direction of the current-carrying bus bar, which achieves stable fastening with bolts. In addition, parts aside from the bolt insertion holes in the central region are solid along the entire length in the length direction, and the hollow duct that passes through the length direction is provided in a side region. As a result, the central region and the pair of side regions of the current carrying bus bar with the distinctive structure that is disclosed here can be easily manufactured by extrusion molding.

It is preferable for the bolt fastening portion of the current-carrying bus bar to be bolted directly to the connector portion of the heat-generating component. By bolting the bolt fastening portion of the current-carrying bus bar directly to the connector portion of the heat-generating component, the heat generated by the heat-generating component can be transferred directly from the connector portion of the heat-generating component to the current-carrying bus bar, so that the heat can be quickly dissipated by the current carrying bus bar through which the refrigerant circulates. As a result, the heat dissipation efficiency of the heat-generating component can be further improved compared to a conventional structure where a bus bar had to extend to an object used as a heat dissipater.

It is preferable for the bolt fastening portion of the current-carrying bus bar to include a first bolt fastening portion provided on the first end side and a second bolt fastening portion provided on the other end side, and for the first bolt fastening portion and the second bolt fastening portion to be directly bolted to the connector portions of a pair of the heat generating components that are disposed adjacent to each other. By connecting the connector portions of the heat-generating components that are adjacently arranged to the first bolt fastening portion and the second bolt fastening portion of the current-carrying bus bar, the current-carrying bus bar according to the present disclosure can be directly fastened to a pair of heat-generating components, so that heat can be dissipated from the heat-generating component via the current-carrying bus bar with favorable heat dissipation efficiency. In addition, since the heat dissipation efficiency can be favorably maintained while shortening the length of the current-carrying bus bar with the distinctive structure disclosed in this specification, it is possible to improve the heat dissipation efficiency of the heat-generating component in a compact manner and at low cost.

It is preferable for the connector portions of the pair of heat generating components that are disposed adjacent to each other to be provided so as to be exposed at top surfaces of the heat generating components and for the current-carrying bus bar to be mounted on the top surfaces of the heat generating components. By connecting the first and second bolt fastening portions of the current-carrying bus bar to the connector portions provided on the top surfaces of the pair of heat-generating components, the current-carrying bus bar can be placed on the top surfaces of the heat-generating components. As a result, even if the refrigerant supply pipe and the refrigerant return pipe that are routed from both ends of the current-carrying bus bar are provided with surplus length to absorb tolerances, space for absorbing such surplus length can be provided via the height dimension of the heat-generating components, which further improves the ease of assembly of the circuit assembly.

It is preferable for an opening of the connector portion of the heat generating component and an opening of a bolt fastening portion of the current-carrying bus bar to be in perpendicular directions and for the connector portion and the bolt fastening portion to be connected by bolting both ends of a connecting fastener, which is bent in an L shape, with respect to the connector portion and the bolt fastening portion. The connector portion and the bolt fastening portion are connected by fastening both ends of the connecting fastener, which is bent into an L shape, with respect to the connector portion and the bolt fastening portion using bolts. This means that even if it is difficult to directly connect a bolt fastening portion of the current-carrying bus bar to a connector portion of a heat generating component due to the arrangement of the heat generating component for example, the connector portion and the bolt fastening portion can be connected over a short connection distance via a separate L-shaped connecting fastener. As a result, it is possible to advantageously suppress a drop in heat dissipation efficiency of the heat-generating component even when it is difficult to directly connect the bolt fastening portion of the current-carrying bus bar to the connector portion of the heat-generating component.

### Detailed Description of Embodiments of the Present Disclosure

Preferred embodiments of a circuit assembly according to the present disclosure will now be described with reference to the drawings. It should be noted that the present disclosure is not limited to these examples, but is defined by the claims, and is intended to include all modifications which fall within the scope of the claims and the meaning and scope of equivalents thereof.

### First Embodiment

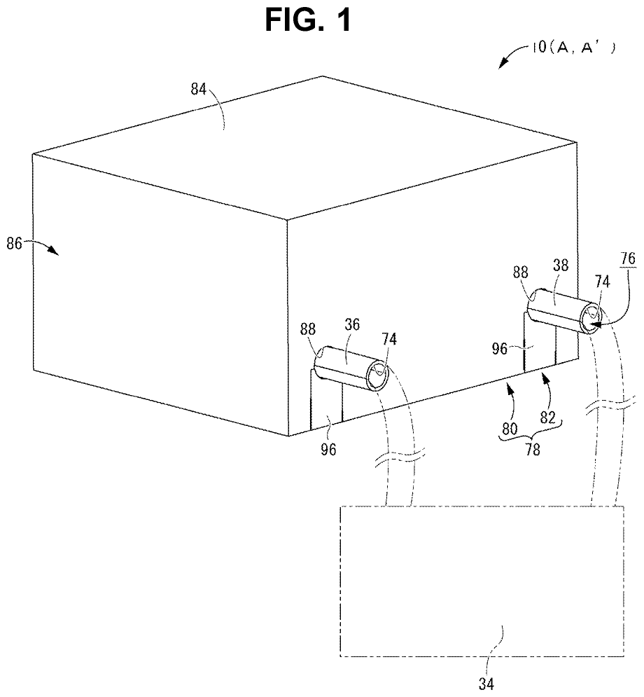

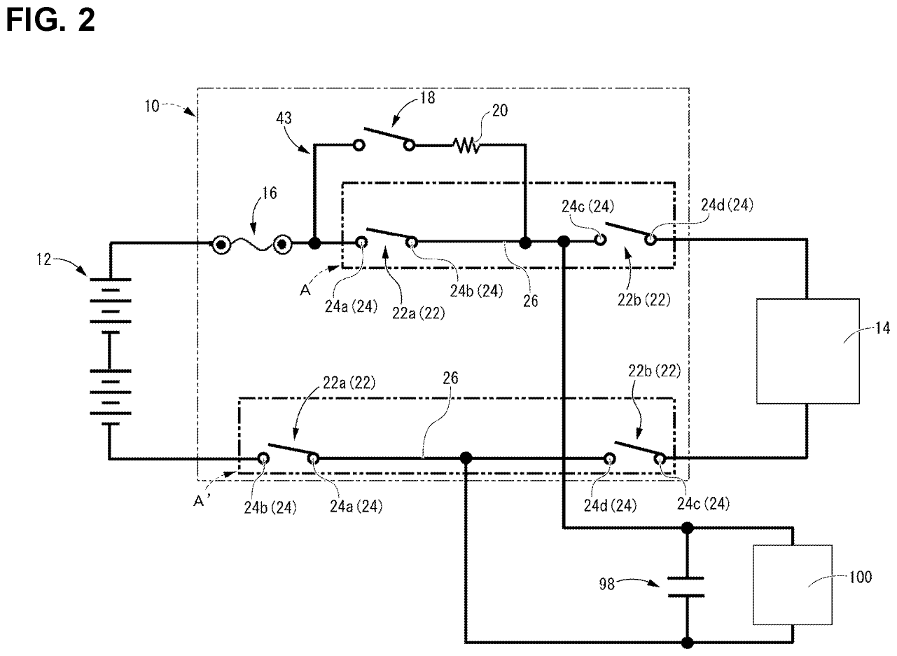

A circuit assembly 10 according to a first embodiment of the present disclosure is described below with reference to FIG. 1 to FIG. 7. Like in the specific example of a circuit diagram depicted in FIG. 2, the circuit assembly 10 is installed in a vehicle (not illustrated), such as an electric vehicle or a hybrid vehicle, and supplies and controls power from a power source 12, such as a battery, to a load 14, such as a motor. Note that although as depicted in FIG. 2, a fuse 16, a precharge relay 18, a precharge resistor 20, and the like that are provided in the circuit from the power source 12 to the load 14 may also be installed in the circuit assembly 10, in FIGS. 1 and 3 to 7, the parts indicated as “A” and “A” in FIG. 2, which are the principal parts for the present disclosure, will be described as the circuit assembly 10. Also, although the circuit assembly 10 is internally provided with the two principal parts, A and A′ as depicted in FIG. 2, since these parts have the same form, only part A will be described and description of the other part A′ is omitted.

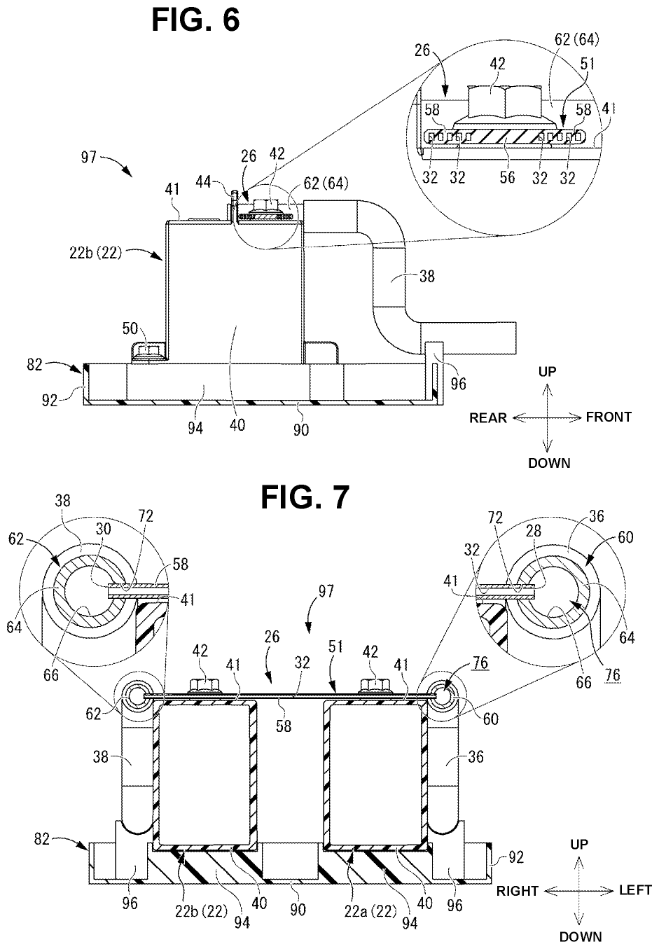

Although the circuit assembly 10 can be disposed in any orientation, in the following description, the expression “upward” refers to upward in FIG. 6, “downward” refers to downward in FIG. 6, “the front” refers to the right in FIG. 5, “the rear” refers to the left in FIG. 5, “the left” refers to downward in FIG. 5, and “the right” refers to upward in FIG. 5. When a plurality of components are the same, reference numerals may be assigned to only some of such components and the reference numerals of other components may be omitted.

### Circuit Assembly 10

The circuit assembly 10 includes relays 22 as heat generating components, and a current-carrying bus bar 26 that is connected to connector portions 24 of the relays 22. The current-carrying bus bar 26 includes hollow ducts 32 which each include a first opening 28 and a second opening 30. A refrigerant supply pipe 36, which supplies refrigerant from a refrigerant source 34 (depicted by a chain double-dashed line in FIG. 1), is connected to the first openings 28 of the hollow ducts 32, and a refrigerant return pipe 38 that returns the refrigerant to the refrigerant source 34 is connected to the second openings 30 of the hollow ducts 32.

### Heat Generating Components (Relays 22)

In this first embodiment, a pair of relays 22, 22 are disposed so as to be spaced apart in the left right direction, with a first relay 22a being provided on the left side and a second relay 22b on the right side. The first and second relays 22a, 22b are disposed relatively close to each other, that is, the first and second relays 22a, 22b are disposed adjacent to each other. The first and second relays 22a, 22b each include a relay body 40, 40 that is substantially cuboid in shape. The first and second relays 22a, 22b are both disposed facing upward, with a pair of connector portions 24, 24 provided on a top surface 41 of each of the first and second relays 22a, 22b so as to be spaced apart in the front-rear direction.

That is, the first relay 22a is provided with a first positive electrode-side connector portion 24a and a first negative electrode-side connector portion 24b, and the second relay 22b is provided with a second positive electrode-side connector portion 24c and a second negative electrode-side connector portion 24d. In other words, the respective connector portions (that is, the first and negative positive electrode-side connector portions 24a, 24b and the second positive and negative electrode-side connector portions 24c, 24d) of a pair of heat generating components (that is, the first and second relays 22a, 22b) disposed adjacent to each other are provided so as to be exposed at the top surface 41 of each heat generating component (the first and second relays 22a, 22b).

Note that in this first embodiment, the first and second relays 22a, 22b are each formed in shapes which, including leg portions 46 described later, have rotational symmetry around a center axis that extends in the vertical direction, with the second relay 22b being disposed in a state where the second relay 22b is rotated by 180 degrees around this center axis that extends in the vertical direction relative to the first relay 22a. By doing so, in this first embodiment, the first negative electrode-side connector portion 24b and the second positive electrode-side connector portion 24c are disposed so as to be spaced apart in the left-right direction, and the first positive electrode-side connector portion 24a and the second negative electrode-side connector portion 24d are disposed so as to be spaced apart in the left-right direction. The first negative electrode-side connector portion 24b and the second positive electrode-side connector portion 24c are connected by the current-carrying bus bar 26, so that as depicted in FIG. 2, the first relay 22a and the second relay 22b are electrically connected in series.

In more detail, the current carrying bus bar 26 is provided with a pair of bolt insertion holes 52, 52, described later, with the first negative electrode-side connector portion 24b and the second positive electrode-side connector portion 24c communicating with this pair of bolt insertion holes 52, 52. Bolts 42 are inserted through this pair of bolt insertion holes 52, 52, and the respective bolts 42 are fastened to the first negative electrode-side connector portion 24b and the second positive electrode-side connector portion 24c. By doing so, bolt fastening portions 54 (that is, a first bolt fastening portion 54a and second bolt fastening portion 54b), described later, of the current-carrying bus bar 26 are directly fastened by bolts to the first negative electrode-side connector portion 24b and the second positive electrode-side connector portion 24c.

In addition, in the principal part A in FIG. 2, a conductive member such as a bus bar is connected to the first positive electrode-side connector portion 24a, and in this first embodiment, this conductive member extends to the outside of a case 78 (described later) of the circuit assembly 10 via the fuse 16 and is electrically connected to a positive electrode-side terminal of the power source 12. In the same way, a conductive member such as a bus bar is connected to the second negative electrode-side connector portion 24d and this conductive member extends to the outside of the case 78 of the circuit assembly 10 and is electrically connected to the negative electrode-side terminal of the load 14. Note that a precharge circuit 43 including the precharge relay 18 and the precharge resistor 20 is provided between the conductive member connected to the first positive electrode-side connector portion 24a and the current-carrying bus bar 26 so as to bypass the first relay 22a.

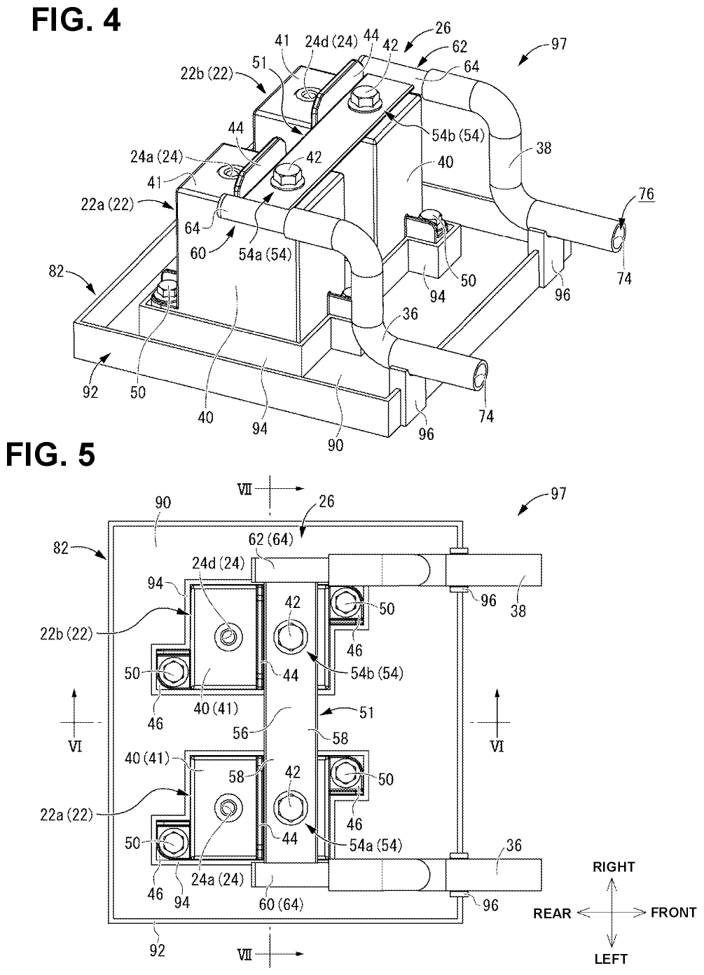

In addition, in the principal part A′ in FIG. 2, a conductive member such as a bus bar is connected to the first negative electrode-side connector portion 24b of the first relay 22a. This conductive member extends to the outside of the case 78 (described later) of the circuit assembly 10 and is electrically connected to the negative electrode-side terminal of the power source 12. In the same way, a conductive member such as a bus bar is connected to the second positive electrode-side connector portion 24c of the second relay 22b. This conductive member extends to the outside of the case 78, described later, of the circuit assembly 10 and is electrically connected to the positive electrode-side terminal of the load 14. In the principal part A′in FIG. 2, the first positive electrode-side connector portion 24a and the second negative electrode-side connector portion 24d are electrically connected by the current-carrying bus bar 26. In other words, in the principal part A′ in FIG. 2, the two connector portions positioned at the rear of a lower assembly 97, described later, as depicted in FIG. 4 and the like (that is, the first positive electrode-side connector portion 24a and the second negative electrode-side connector portion 24d) are connected by the current-carrying bus bar 26.

In addition, partition plates 44 are provided so as to protrude upward between the first positive electrode-side connector portion 24a and the first negative electrode-side connector portion 24b of the first relay 22a and between the second positive electrode-side connector portion 24c and the second negative electrode-side connector portion 24d of the second relay 22b. In addition, the leg portions 46 that protrude outward on both sides in the front-rear direction are provided at a lower end of each relay body 40. These leg portions 46 are provided with bolt insertion holes 48 that pass through in the vertical direction, with bolts 50 being inserted through these bolt insertion holes 48 to fix the first and second relays 22a, 22b to a lower case 82 that is included in the case 78, described later.

### Current-Carrying Bus Bar 26

The current-carrying bus bar 26 includes a bus bar body 51 in the overall shape of a substantially rectangular plate that extends in the left-right direction. The bus bar body 51 is formed of a metal with favorable electrical conductivity, such as copper (which includes copper alloy) or aluminum (which includes aluminum alloy). The bus bar body 51 includes a bolt fastening portion 54 with bolt insertion holes 52, and the hollow ducts 32 that extend through the inside of the current-carrying bus bar 26 and each include a first opening 28 that is open at one end (the left end) in the length direction of the current-carrying bus bar 26 and a second opening 30 that is open at the other end (the right end). That is, the part of the bus bar body 51 in the periphery of the circular bolt insertion holes 52 forms the bolt fastening portion 54.

In the first embodiment, a pair of bolt insertion holes 52, 52 (or “bolt fastening portions 54, 54”) are provided in a central part in the width direction (the front-rear direction) of the bus bar body 51 and are spaced apart in the length direction (the left-right direction). That is, a first bolt fastening portion 54a is provided at one end (the left end) of the bus bar body 51 and a second bolt fastening portion 54b is provided at the other end (the right end), with the bolt fastening portions 54, 54 including the first bolt fastening portion 54a and the second bolt fastening portion 54b. The first and second bolt fastening portions 54a, 54b are each provided with a bolt insertion hole 52. Note that although there are no limitations on the method of forming this bus bar body 51, in this first embodiment, the bus bar body 51 is formed by extrusion molding.

In more detail, as depicted in FIG. 6, the bus bar body 51 includes a central region 56 that extends with a predetermined width in the central part in the width direction (the front-rear direction), and a pair of side regions 58, 58 that extend with a predetermined width on both sides in the width direction of the central region 56. Note that during extrusion molding of the bus bar body 51, the central region 56 is formed so as to be solid along its entire length in the length direction (the left-right direction), and the pair of bolt insertion holes 52, 52 are formed after the bus bar body 51 has been molded. By doing so, the central region 56 is formed solid along its entire length in the length direction (the left-right direction) except for the bolt insertion holes 52.

Also, as depicted in FIGS. 6 and 7, the hollow ducts 32 that extend along the entire length in the length direction are provided in both of the pair of side regions 58, 58. Although there are no limitations on the size, cross-sectional shape, number, and the like of these hollow ducts 32, in this first embodiment, five hollow ducts 32, which are substantially rectangular in cross section, are provided in each side region 58, so as to be spaced apart in the front-rear direction. Each of the total of ten hollow ducts 32 is open at the first openings 28 and the second openings 30 at both the left and right ends.

In addition, the current-carrying bus bar 26 includes a first connecting pipe 60 that is connected in a fluid-tight manner to one end (the left end) of the bus bar body 51, surrounds each first opening 28, and communicates with each first opening 28, and a second connecting pipe 62 that is connected in a fluid-tight manner to the other end (the right end) of the bus bar body 51, surrounds each second opening 30 and communicates with each second opening 30. Each of the first and second connecting pipes 60, 62 is a hollow pipe that extends in the front-rear direction and is provided with a peripheral wall 64 shaped as a substantially circular tube and an inner hole 66 that extends in the front-rear direction inside the peripheral wall 64.

Note that the first and second connecting pipes 60, 62 both have a rear opening that is covered and are both open at the front. The front openings of the first and second connecting pipes 60, 62 respectively form a first pipe connection port 68 and a second pipe connection port 70 to which the refrigerant supply pipe 36 and the refrigerant return pipe 38 are connected. The first and second connecting pipes 60, 62 are preferably made of metal, but do not need to be made of the same material as the bus bar body 51 and do not need to exhibit favorable electrical conductivity. That is, the first and second connecting pipes 60, 62 do not need to be electrically conductive and may be made of an insulating synthetic resin, for example.

Through holes 72 for connecting to both ends of the bus bar body 51 are formed in each peripheral wall 64 of the first and second connecting pipe bodies 60, 62. That is, the through holes 72 are rectangular in shape to roughly correspond to both ends of the bus bar body 51 and are formed so as to radially pass through the peripheral walls 64 inwardly (that is, in the left-right direction) in respectively opposite directions. One end (the left end) of the bus bar body 51 is inserted into the through hole 72 of the first connecting pipe 60, and by attaching the outer peripheral surface of the peripheral wall 64 and the inner peripheral surface of the through hole 72 to each other by welding, adhesive, or the like, one end of the bus bar body 51 and the first connecting pipe 60 are connected in a fluid-tight manner.

In the same way, the other end (the right end) of the bus bar body 51 is inserted into the through hole 72 of the second connecting pipe 62, and by attaching the outer peripheral surface of the peripheral wall 64 and the inner peripheral surface of the through hole 72 to each other by welding, adhesive, or the like, one end of the bus bar body 51 and the second connecting pipe 62 are connected in a fluid-tight manner. In the first embodiment, the first and second connecting pipes 60, 62 protrude toward the front, that is, to the side of the bus bar body 51, and the openings (that is, the first and second pipe connection ports 68, 70) of the first and second connecting pipes 60, 62 are provided at the front in this protruding direction.

As a result, the first opening 28 of each hollow duct 32 provided at the left end of the bus bar body 51 is exposed to the inside of the peripheral wall 64 of the first connecting pipe 60, so that each hollow duct 32 and the inner hole 66 of the first connecting pipe 60 are interconnected. In the same way, the second opening 30 of each hollow duct 32 provided at the left end of the bus bar body 51 is exposed to the inside of the peripheral wall 64 of the second connecting pipe 62, so that each hollow duct 32 and the inner holes 66 of the second connecting pipe 62 are interconnected.

### Refrigerant Supply Pipe 36 and Refrigerant Return Pipe 38

In this first embodiment, the refrigerant supply pipe 36 and the refrigerant return pipe 38 are each composed of a rubber tube that is made of rubber (which includes elastomers), so that the refrigerant supply pipe 36 and the refrigerant return pipe 38 are both flexible and capable of elastic deformation. That is, the first pipe connection port 68 of the first connecting pipe 60 is inserted in a substantially press-fitted state into the rear opening of the refrigerant supply pipe 36, thereby interconnecting the first connecting pipe 60 and the refrigerant supply pipe 36 in a fluid-tight manner. In the same way, the second pipe connection port 70 of the second connecting pipe 62 is inserted in a substantially press-fitted state into the rear opening of the refrigerant return pipe 38, thereby interconnecting the second connecting pipe 62 and the refrigerant return pipe 38 in a fluid-tight manner. By doing so, the refrigerant supply pipe 36 and the refrigerant return pipe 38 extend forward from the first and second connecting pipes 60, 62, respectively, with inner holes 74 in the refrigerant supply pipe 36 and the refrigerant return pipe 38 in communication with the inner holes 66 in the first and second connecting pipes 60, 62, respectively.

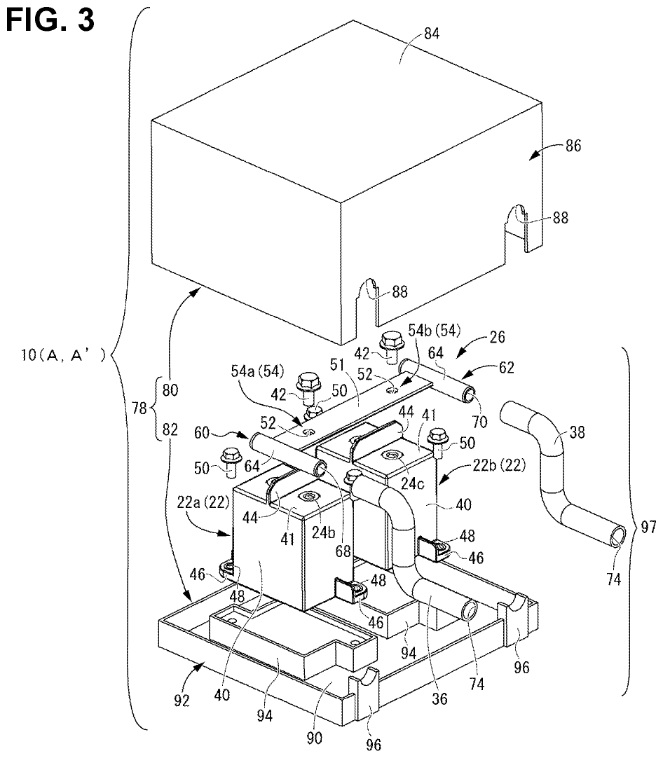

Note that the refrigerant supply pipe 36 and the refrigerant return pipe 38 may each have a predetermined shape, for example, as depicted in FIG. 3, the refrigerant supply pipe 36 and the refrigerant return pipe 38 may extend forward from the first pipe connection port 68 and the second pipe connection port 70, bend downward, and then extend forward again at their lower ends. Alternatively, the refrigerant supply pipe 36 and the refrigerant return pipe 38 do not need to have specified shapes, and when assembling the circuit assembly 10, the refrigerant supply pipe 36 and the refrigerant return pipe 38 may be arranged so as to be bent downward relative to the first and second pipe connection ports 68, 70 by being sandwiched between and supported by an upper case 80 and a lower case 82, described later.

The ends of the refrigerant supply pipe 36 and the refrigerant return pipe 38 at the opposite side to the ends connected to the first and second connecting pipes 60, 62 are connected to the refrigerant source 34. By connecting the refrigerant supply pipe 36 and the refrigerant return pipe 38 to the refrigerant source 34 in this way, a refrigerant flow path 76 is formed that extends from the refrigerant source 34 via the refrigerant supply pipe 36, the first connecting pipe 60, the bus bar body 51 (the hollow ducts 32), the second connecting pipe 62, and the refrigerant return pipe 38 so as to return to the refrigerant source 34.

There are no limitations on the refrigerant flowing through the refrigerant flow path 76, but is preferable for the refrigerant to be electrically insulating, with examples of insulating refrigerants including Fluorinert (registered trademark) and Novec (registered trademark) manufactured by 3M. As the refrigerant source 34, as examples, a chiller (that is, a refrigerant circulating system) including a pump or the like, not illustrated, may be provided separately, or a chiller already installed in the vehicle may be used. By using a chiller including a pump as the refrigerant source 34, it is possible to cause the refrigerant to flow on the refrigerant flow path 76. Note that the installed location of the pump is not limited to the refrigerant source 34 (that is, between the refrigerant supply pipe 36 and the refrigerant return pipe 38), and the pump may be disposed at any appropriate location on the refrigerant flow path 76.

### Case 78

In the first embodiment, the first and second relays 22a, 22b, the current-carrying bus bar 26, and the like are housed in a case 78 made of synthetic resin, metal, or the like. In particular, in the first embodiment, the case 78 includes the upper case 80 on the top and the lower case 82 on the bottom. The upper case 80 and the lower case 82 can be assembled to and separated from each other in the vertical direction. Note that in FIG. 1 and FIGS. 3 to 7, the first and second relays 22a, 22b, the current-carrying bus bar 26, and the like that constitute the principal part A in FIG. 2 are housed in the case 78. However, as described earlier, in addition to these components, the case 78 may also house the first and second relays 22a, 22b, the current-carrying bus bar 26, the fuse 16, the pre-charge relay 18, the pre-charge resistor 20, and the like that constitute the principal part A′ in FIG. 2.

The upper case 80 is substantially box shaped as a whole, is open to below, and includes an upper bottom wall portion 84, which is substantially rectangular when viewed from above, and an upper peripheral wall portion 86, which protrudes downward from the outer edge of the upper bottom wall portion 84. Pipe insertion portions 88, through which the refrigerant supply pipe 36 and the refrigerant return pipe 38 that protrude forward are inserted, are provided at a front part of the upper peripheral wall portion 86, are open to below, and pass through the upper peripheral wall portion 86 in the front-rear direction.

The lower case 82 is substantially box-shaped as a whole, is open to above, and includes a bottom wall portion 90, which is substantially rectangular when viewed from above, and a lower peripheral wall portion 92, which protrudes upward from the outer edge of the bottom wall portion 90. The bottom wall portion 90 is provided with a pair of relay mounting portions 94, 94 that protrude upward. The first and second relays 22a, 22b are mounted on the relay mounting portions 94, 94. Pipe support portions 96 for supporting the refrigerant supply pipe 36 and the refrigerant return pipe 38 are provided at a front part of the lower peripheral wall portion 92 and protrude upward.

### Assembly Process of Circuit Assembly 10

Next, a specific example of the assembly process of the circuit assembly 10 will be described. Note that the assembly process of the circuit assembly 10 is not limited to the description given below.

First, the first and second relays 22a, 22b are placed facing upward on the relay mounting portions 94 of the lower case 82, and then fixed in place with the bolts 50. After this, the first and second bolt fastening portions 54a, 54b of the current-carrying bus bar 26 are placed on top of the top surfaces 41 of the first and second relays 22a, 22b at parts that are closer to the front than the partition plates 44, and the first negative electrode-side connector portion 24b and the second positive electrode-side connector portion 24c are placed in communication with the bolt insertion holes 52. The bolts 42 are then inserted through the bolt insertion holes 52 and fastened to the first negative electrode-side connector portion 24b and the second positive electrode-side connector portion 24c, thereby bolting the current-carrying bus bar 26 to the first and second relays 22a, 22b.

Next, the refrigerant supply pipe 36 and the refrigerant return pipe 38 are connected to the first and second pipe connection ports 68, 70 of the first and second connecting pipes 60, 62, respectively. By doing so, the lower assembly 97 is completed, as depicted in FIGS. 4 to 7. Note that the refrigerant supply pipe 36 and the refrigerant return pipe 38 may be fixed to the first and second pipe connection ports 68, 70 before the current-carrying bus bar 26 is fixed to the first and second relays 22a, 22b.

After this, the refrigerant supply pipe 36 and the refrigerant return pipe 38 that extend to the front from the first and second pipe connection ports 68, 70 are placed on the pipe support portions 96 of the lower case 82, the upper case 80 is assembled from above onto the lower case 82, and the lower case 82 and the upper case 80 are fixed together by a locking mechanism or the like, not illustrated. By doing so, the case 78 is completed, which completes the circuit assembly 10 at the same time. In the circuit assembly 10, the refrigerant supply pipe 36 and the refrigerant return pipe 38 are sandwiched between the pipe insertion portions 88 and the pipe support portions 96 in the vertical direction, with the refrigerant supply pipe 36 and the refrigerant return pipe 38 protruding toward the front from the case 78.

The circuit assembly 10 assembled as described above is housed and disposed inside the case of a battery pack of a hybrid vehicle or an electric vehicle, for example. In the circuit assembly 10, the opposite ends of the refrigerant supply pipe 36 and the refrigerant return pipe 38 to the ends connected to the first and second pipe connection ports 68, 70 are connected to the refrigerant source 34. As depicted in FIG. 2 described earlier, in the principal part A, the first positive electrode-side connector portion 24a is electrically connected to the positive electrode-side terminal of the power source 12 and the second negative electrode-side connector portion 24d is electrically connected to the negative electrode-side terminal of the load 14. In addition, the first negative electrode-side connector portion 24b of the principal part A′ is electrically connected to the negative electrode-side terminal of the power source 12, and the second positive electrode-side connector portion 24c is electrically connected to the positive electrode-side terminal of the load 14.

In the first embodiment, as depicted in FIG. 2, a conductive member, such as a bus bar, is electrically connected to an intermediate part of the current-carrying bus bars 26 in the principal parts A and A′, with a capacitor 98 and an inverter 100 being connected in parallel to these intermediate parts. That is, in an electric circuit that extends from the power source 12 via the circuit assembly 10 in the principal part A, the load 14, and the circuit assembly 10 in the principal part A′ before returning to the power source 12, the capacitor 98 and the inverter 100 are connected as branches downstream of the first relay 22a in the principal part A (that is, upstream of the second relay 22b) and upstream of the first relay 22a in the principal part A′ (that is, downstream of the second relay 22b). Note that the inverter 100 can be connected via a cable or the like to a household power outlet, for example, and can convert the power obtained from the household outlet into direct current and store the power in the capacitor 98.

In the circuit assembly 10 connected to an electric circuit as described above, when the first and second relays 22a, 22b in the principal part A and the first and second relays 22a, 22b in the principal part A′ are both in an ON state, power is supplied from the power source 12 to the load 14, and a motor, which is a specific example of the load 14, is driven. Note that even if the first relay 22a in the principal part A is shut off due to detection of an abnormal current or the like, a electricity will bypass the first relay 22a and flow through the precharge circuit 43, so that power is supplied from the power source 12 to the load 14 to drive a motor, for example. When an abnormal current has been detected and the fuse 16 and the first relays 22a in the principal parts A and A′ are turned off (that is, during power failure), the second relays 22b in the principal parts A and A′ are turned on to constitute a power path from the capacitor 98 to the load 14. By doing so, it is possible to supply power stored in the capacitor 98 to the load 14, which makes it possible to drive a motor, for example.

Alternatively, by turning on the first relays 22a and turning off the second relays 22b in the principal parts Aand A′, a power path is constituted from the power source 12 to the inverter 100. By doing so, it is possible to convert the power of the power source 12 to AC and extract this power via a cable or the like connected to the inverter 100 as power for household use.

According to the circuit assembly 10 described above, although the first and second relays 22a, 22b in the principal parts A, A′ will generate heat when current passes through the first and second relays 22a, 22b, since the current-carrying bus bar 26 that is connected between the first and second relays 22a, 22b is provided with the hollow ducts 32 and the refrigerant flow path 76 on which the refrigerant flows include these hollow ducts 32. By enabling the refrigerant to flow through the current-carrying bus bar 26 in this way, it is possible to avoid an increase in temperature of the current-carrying bus bar 26 and heat generated at each of the first and second relays 22a, 22b can also be removed.

Since the refrigerant flow path 76 includes the hollow ducts 32 provided inside the current-carrying bus bar 26, an increase in size of the current-carrying bus bar 26 and in turn the circuit assembly 10 itself can be prevented compared to a case where the refrigerant flow path is provided outside the current-carrying bus bar 26. In particular, since a cooling structure can be realized using the current-carrying bus bar 26, there is no need to provide a separate structure for dissipating heat or the like, which achieves the effects of simplifying the structure and improving the efficiency of assembly work.

The current-carrying bus bar 26 includes the first and second connecting pipes 60, 62, with the first opening 28, which is an opening at one end of each hollow duct 32, connected via the first connecting pipe 60 to the refrigerant supply pipe 36 and the second opening 30, which is an opening at the other end of each hollow duct 32, connected via the second connecting pipe 62 to the refrigerant return pipe 38. In other words, the refrigerant supply pipe 36 and the refrigerant return pipe 38, which are made of rubber tubes, are not directly connected to the current-carrying bus bar 26 and are instead connected to the first and second connecting pipes 60, 62, which are tubular in shape. This makes it easy to connect the refrigerant supply pipe 36 and the refrigerant return pipe 38 to the hollow ducts 32, and also ensures that fluid-tight connections can be stably achieved on the refrigerant flow path 76.

The first and second connecting pipes 60, 62 protrude to the front from the bus bar body 51, with the front openings of the first and second connecting pipes 60, 62 forming the first and second pipe connection ports 68, 70, respectively. In other words, the refrigerant that flows from each hollow duct 32 into each inner hole 66 of the first and second connecting pipes 60, 62 is prevented from flowing to the rear from each hollow duct 32, which reduces the risk of the refrigerant stagnating in parts of the inner holes 66 of the first and second connecting pipes 60, 62 located to the rear of the hollow ducts 32.

The bus bar body 51 of the current carrying bus bar 26 includes the central region 56 in a central part in the width direction and the pair of side regions 58, 58 on both sides in the width direction. The central region 56 is solid in shape except for the bolt insertion holes 52 and is formed with a constant cross-sectional shape along the entire length of the bus bar body 51 in the length direction (the left-right direction), with each side region 58 being provided with a plurality of hollow ducts 32 that extend along the entire length of the bus bar body 51 in the length direction. As a result, the bus bar body 51 extends in the left-right direction with a substantially constant cross-sectional shape aside from at the bolt insertion holes 52, which means that the bus bar body 51 can be easily manufactured by forming the bolt insertion holes 52 after extrusion molding.

The bolt fastening portions 54 (the first and second bolt fastening portions 54a, 54b) of the current-carrying bus bar 26 are directly bolted to the first negative electrode-side connector portion 24b and the second positive electrode-side connector portion 24c of the first and second relays 22a, 22b. By doing so, it is possible for the current-carrying bus bar 26, which provides performs cooling, to come into direct contact with the first and second relays 22a, 22b, which are the heat-generating components, thereby improving the cooling efficiency. No other members are used to connect the current-carrying bus bar 26 to the first and second relays 22a, 22b, which can avoid an increase in the number of components.

In particular, the first and second relays 22a, 22b are disposed adjacent to each other, and the first and second bolt fastening portions 54a, 54b of the current-carrying bus bar 26 are directly bolted to the first negative electrode-side connector portion 24b and the second positive electrode-side connector portion 24c of the first and second relays 22a, 22b. By doing so, it is possible to suppress the length dimension of the current-carrying bus bar 26 and to connect the first and second relays 22a, 22b at a short distance, which also improves the conduction efficiency for electric current.

The first and second relays 22a, 22b are disposed facing upward, the connector portions 24 of the first and second relays 22a, 22b are exposed at the top surfaces 41 of the first and second relays 22a, 22b, and the current-carrying bus bar 26 is mounted on the top surfaces 41 of the first and second relays 22a, 22b. This makes it possible to provide space in the vertical direction at the first and second relays 22a, 22b, and by using this vertical space, the refrigerant supply pipe 36 and the refrigerant return pipe 38 can be disposed by bending them downward, for example. By forming the refrigerant supply pipe 36 and the refrigerant return pipe 38 from an elastically deformable material such as rubber, any tolerances between the current-carrying bus bar 26 and the refrigerant source 34 can be absorbed by elastic deformation of the refrigerant supply pipe 36 and/or the refrigerant return pipe 38. In particular, by providing bent parts in advance in the refrigerant supply pipe 36 and/or the refrigerant return pipe 38, these bent parts will preferentially deform, which means the effect of absorbing any tolerances through elastic deformation can be achieved more stably.

### Second Embodiment

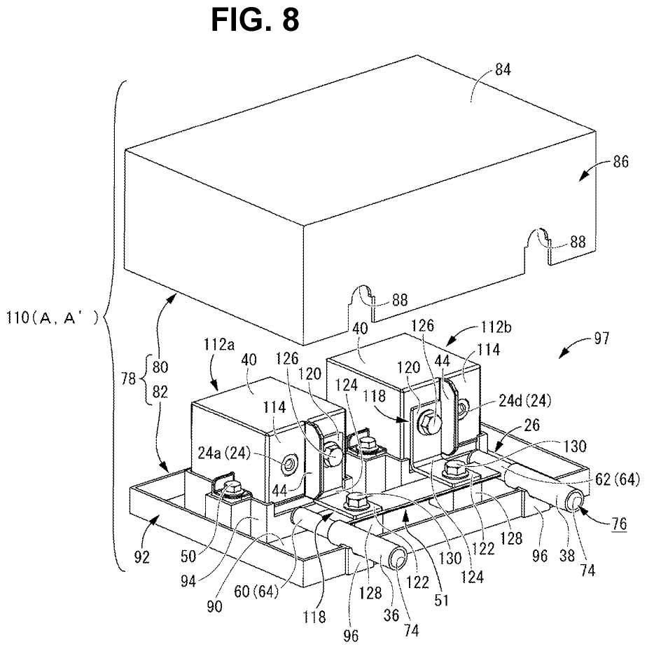

Next, a circuit assembly 110 according to a second embodiment of the present disclosure will be described with reference to FIG. 8. The circuit assembly 110 according to the second embodiment has the same basic structure as the circuit assembly 10 according to the first embodiment but differs in that although the first and second relays 22a, 22b are disposed facing upward in the circuit assembly 10 according to the first embodiment, first and second relays 112a, 112b in the circuit assembly 110 according to the second embodiment are disposed facing the front. In the following description, differences from the first embodiment will be described, and components and parts that are essentially the same have been assigned the same reference numerals as in the first embodiment in the drawings and detailed description will be omitted.

Note that the principal parts A, A′ according to the present disclosure depicted in FIG. 2 are also indicated for the circuit assembly 110 depicted in FIG. 8, and in addition to the first and second relays 112a, 112b and the current-carrying bus bar 26 that constitute the principal part A, the first and second relays 112a, 112b and the current-carrying bus bar 26 that constitute the principal part A′, the fuse 16, the pre-charge relay 18, the pre-charge resistor 20, and the like can be housed inside the case 78 of the circuit assembly 110.

### First and Second Relays 112a, 112b

As described above, in this second embodiment, the first and second relays 112a, 112b are disposed facing the front. That is, the first positive and negative connector portions 24a, 24b of the first relay 112a and the second positive and negative connector portions 24c, 24d of the second relay 112b are both exposed at the front surfaces 114 of the first and second relays 112a, 112b. The first negative electrode-side connector portion 24b and the second positive electrode-side connector portion 24c, which are spaced apart in the left-right direction, are electrically connected by the current-carrying bus bar 26.

Note that in the second embodiment, the structure of the current-carrying bus bar 26 is the same as in the first embodiment, with the pair of bolt insertion holes 52, 52 (that is, the first and second bolt fastening portions 54a, 54b) being provided on both sides in the left-right direction of the bus bar body 51 and the first and second connecting pipes 60, 62 being connected to the left and right ends respectively of the bus bar body 51. That is, in this second embodiment, the first negative electrode-side connector portion 24b and the second positive electrode-side connector portion 24c are both exposed at the front, and the bolt insertion holes 52 of the first and second bolt fastening portions 54a, 54b are openings in the vertical direction. With this configuration, the openings of the first negative electrode-side connector portion 24b and the second positive electrode-side connector portion 24c and the openings of the bolt insertion holes 52 in the first and second bolt fastening portions 54a, 54b are in mutually perpendicular directions.

### Connection Fasteners 118

The first negative electrode-side connector portion 24b and the second positive electrode-side connector portion 24c are connected to the first and second bolt fastening portions 54b by connecting fasteners 118 that are each bent into an L shape. That is, the connecting fastener 118 includes an upper fastener 120 and a lower fastener 122 which are each in the shape of substantially rectangular plate, with the upper fastener 120 and the lower fastener 122 being connected by a bent part 124. Each of the upper fastener 120 and the lower fastener 122 has a bolt insertion hole (not illustrated) that passes through in the plate thickness direction. That is, a bolt insertion hole is formed at both ends in the length direction of each connecting fastener 118.

The upper fastener 120 of the connecting fastener 118 is placed over the first negative electrode-side connector portion 24b and the second positive electrode-side connector portion 24c from the front, so that the first negative electrode-side connector portion 24b and the second positive electrode-side connector portion 24c become aligned with the bolt insertion holes of the upper fasteners 120. Bolts 126 are inserted into these bolt insertion holes and fastened to the first negative electrode-side connector portion 24b and the second positive electrode-side connector portion 24c, thereby bolting the first negative electrode-side connector portion 24b and the second positive electrode-side connector portion 24c to the upper fasteners 120.

In the second embodiment, a pair of nut housing portions 128, 128 that protrude upward from the bottom wall portion 90 are provided so as to be spaced apart in the left-right direction on the front part of the lower case 82, and a nut (not illustrated) is housed at the upper end of each nut housing portion 128. The current-carrying bus bar 26 is placed from above on each of these nut housing portions 128, and then the lower fasteners 122 of the connecting fasteners 118 are placed from above on the first and second bolt fastening portions 54a, 54b of the current-carrying bus bar 26.

By doing so, the bolt insertion holes in the lower fasteners 122, the bolt insertion holes 52 in the first and second bolt fastening portions 54a, 54b, and the nuts in the nut housing portions 128 are aligned with one another. The bolts 130 are inserted through the bolt insertion holes in the lower fasteners 122 and through the bolt insertion holes 52 in the first and second bolt fastening portions 54a, 54b and fastened to the nuts in the nut housing portions 128, thereby bolting the first and second bolt fastening portions 54a, 54b to the lower fasteners 122. As a result, the first negative electrode-side connector portion 24b and the second positive electrode-side connector portion 24c become connected to the first and second bolt fastening portions 54a, 54b by bolting them together with the connecting fastener 118 in between.

In the circuit assembly 110 according to the second embodiment with the structure described above, heat generated when current passes through the first and second relays 112a, 112b is transferred to the current-carrying bus bar 26 via the connecting fasteners 118, and due to the cooling effect caused by the refrigerant flowing through the refrigerant flow path 76 including the hollow ducts 32 provided inside the current-carrying bus bar 26, the heat generated at the first and second relays 112a, 112b is eliminated. Accordingly, the circuit assembly 110 according to the second embodiment can achieve the same effects as the circuit assembly 10 according to the first embodiment.

In particular, according to the second embodiment, since the first and second relays 112a, 112b are disposed facing the front, the size in the vertical direction of the first and second relays 112a, 112b and in turn the circuit assembly 110 can be suppressed. Also, in the first embodiment, the current-carrying bus bar 26 is mounted on the top surfaces 41 of the first and second relays 22a and 22b, and the refrigerant supply pipe 36 and the refrigerant return pipe 38 connected to the current-carrying bus bar 26 are bent downward, but in this second embodiment, the current-carrying bus bar 26 is mounted on the nut housing portions 128 on the lower case 82 and the refrigerant supply pipe 36 and the refrigerant return pipe 38 extend linearly to the front without bending in the vertical direction. This can suppress flow of the refrigerant in the vertical direction within the refrigerant flow path 76, which improves the flow efficiency of the refrigerant.

### Other Embodiments

The technology described in this specification is not limited to the embodiments described in the above description and depicted in the drawings. As examples, the following embodiments are also included in the technical scope of the technology described in this specification.
(1) As described earlier, the circuit assemblies 10, 110 depicted in FIGS. 1 and 3 to 8 illustrate a state where the first relays 22a, 112a and the second relays 22b, 112b and the current-carrying bus bar 26 in the principal part A in FIG. 2 are housed in the case 78, and in addition to the above, the case 78 may also house the first relays 22a, 112a, the second relays 22b, 112b and the current-carrying bus bar 26 of the principal part A′, the fuse 16, the pre-charge relay 18, the pre-charge resistor 20, and the like.

Note that the electrical circuit diagram depicted in FIG. 2 is merely one specific example of an electrical circuit to which the circuit assembly according to the present disclosure has been applied, and the case that is included in the circuit assembly may house conventionally known electrical components and the like that are connected in an appropriate way. Accordingly, although the connector portions of the heat generating components (the first negative electrode-side connector portions 24b of the first relays 22a, 112a or the second positive electrode-side connector portions 24c of the second relays 22b, 112b) are directly or indirectly connected to either of the bolt fastening portions 54 (the first bolt fastening portion 54a and the second bolt fastening portion 54b) of the current-carrying bus bar 26 in the embodiments described above, the present disclosure is not limited to this arrangement. In other words, it is sufficient for a connector portion of a heat-generating component to be connected to a bolt fastening portion provided at at least one end of a current-carrying bus bar, and the other end of the current-carrying bus bar may be connected to another current-carrying bus bar, for example. The form of the case that is included in the circuit assembly according to the present disclosure can be changed as appropriate to suit the electrical components and the like housed inside the case.
(2) Although electrically insulating refrigerants such as “Fluorinert (registered trademark)” and “Novec (registered trademark)” are used as examples of the refrigerant flowing through the refrigerant flow path 76 in the embodiments described above, it is also possible to use a refrigerant that is electrically conductive by providing an insulating coating or film on the inner surface of the hollow ducts provided inside the current-carrying bus bar. As one example, water may be used as such a refrigerant.
(3) Although five substantially rectangular hollow ducts 32 are provided in each side region 58 of the bus bar body 51 in the embodiments described above, the present disclosure is not limited to this. The cross-sectional shape of the hollow ducts may be a circle (which includes an oval, an ellipse, a semicircle, and the like), a triangle, or a polygon with five or more sides. The number of hollow ducts in each side region is not limited, and may be one to four, or may be six or more. Note that the hollow ducts do not need to be provided in both the front and rear side regions of the bus bar body and may be provided in only one side region in the front-rear direction.
(4) Although the refrigerant supply pipe 36 and the refrigerant return pipe 38 are both made of rubber tubes and are elastically deformable in the embodiments described above, the pipes may be made of a hard material, for example.
(5) Although the first relays 22a, 112a and the second relays 22b, 112b are given as examples of heat-generating components in the embodiments described above, the present disclosure is not limited to this. Other conventionally known heat-generating components, such as fuses, may be used as the heat-generating components.

### LIST OF REFERENCE NUMERALS

10 Circuit assembly (first embodiment)
12 Power source
14 Load
16 Fuse
18 Pre-charge relay
20 Precharge resistor
22 Relay (heat generating component)
22a First relay
22b Second relay
24 Connector portion
24a First positive electrode-side connector portion
24b First negative electrode-side connector portion
24c Second positive electrode-side connector portion
24d Second negative electrode-side connector portion
26 Current-carrying bus bar
28 First opening
30 Second opening
32 Hollow duct
34 Refrigerant source
36 Refrigerant supply pipe
36 Refrigerant return pipe
40 Relay body
41 Top surface
42 Bolt
43 Pre-charge circuit
44 Partition plate
46 Leg portion
48 Bolt insertion hole
50 Bolt
51 Bus bar body
52 Bolt insertion hole
54 Bolt fastening portion
54a First bolt fastening portion
54b Second bolt fastening portion
56 Central region
58 Side region
60 First connecting pipe
62 Second connecting pipe
64 Peripheral wall
66 Inner hole
68 First pipe connection port
70 Second pipe connection port
72 Through hole
74 Inner hole
76 Refrigerant flow path
78 Case
80 Upper case
82 Lower case
84 Upper bottom wall portion
86 Upper peripheral wall portion
88 Pipe insertion portion
90 Bottom wall portion
92 Lower peripheral wall portion
94 Relay mounting portion
96 Pipe support portion
97 Lower assembly
98 Capacitor
100 Inverter
110 Circuit assembly (second embodiment)
112a First relay
112b Second relay
114 Front surface
118 Connecting fastener
120 Upper fastener
122 Lower fastener
124 Bent part
126 Bolt
128 Nut housing portion
130 Bolt
A, A′ Principal part

1. A circuit assembly comprising:
a heat generating component; and
a current-carrying bus bar that is connected to a connector portion of the heat generating component,
wherein the current-carrying bus bar includes a bolt fastening portion including a bolt insertion hole and a hollow duct, which extends through an inside of the current-carrying bus bar and includes a first opening that is open at a first end in a length direction of the current-carrying bus bar and a second opening that is open at a second end in the length direction of the current-carrying bus bar,
the current-carrying bus bar further includes a first connecting pipe, which is connected in a fluid-tight manner to the first end of the current-carrying bus bar, surrounds the first opening, and communicates with the first opening, and a second connecting pipe, which is connected in a fluid-tight manner to the second end of the current-carrying bus bar, surrounds the second opening, and communicates with the second opening,
the first connecting pipe includes a first pipe connection port that is connectable to an external refrigerant source, and
the second connecting pipe includes a second pipe connection port that is connectable to the refrigerant source.

2. The circuit assembly according to claim 1,
wherein the first pipe connection port of the first connecting pipe protrudes to and is open at a side of the current-carrying bus bar and is connected to a refrigerant supply pipe for supplying the refrigerant from the refrigerant source, and
the second pipe connection port of the second connecting pipe protrudes to and is open at the side of the current-carrying bus bar and is connected to a refrigerant return pipe for returning the refrigerant to the refrigerant source.

3. The circuit assembly according to claim 1,
wherein the current-carrying bus bar includes a central region where a central part in a width direction extends with a predetermined width and a pair of side regions that extend with a predetermined width on both sides in the width direction of the central region,
the central region is formed so that parts aside from the bolt insertion holes are solid along an entire length in the length direction, and
the hollow duct, which passes through in the length direction, are provided in at least one of the side regions.

4. The circuit assembly according to claim 1,
wherein the bolt fastening portion of the current-carrying bus bar is directly bolted to the connector portion of the heat generating component.

5. The circuit assembly according to claim 1,
wherein the bolt fastening portion of the current-carrying bus bar includes a first bolt fastening portion provided on the first end side and a second bolt fastening portion provided on the second end side, and
the first bolt fastening portion and the second bolt fastening portion are directly bolted to the connector portions of a pair of the heat generating components that are disposed adjacent to each other.

6. The circuit assembly according to claim 5,
wherein the connector portions of the pair of the heat generating components that are disposed adjacent to each other are provided so as to be exposed at top surfaces of the heat generating components, and
the current-carrying bus bar is mounted on the top surfaces of the heat generating components.

7. The circuit assembly according to claim 1,
wherein an opening of the connector portion of the heat generating component and an opening of the bolt fastening portion of the current-carrying bus bar are in perpendicular directions, and the connector portion and the bolt fastening portion are connected by bolting both ends of a connecting fastener, which is bent in an L shape, with respect to the connector portion and the bolt fastening portion.
